(19) United States
(12) Patent Application Publication
(10) Pub. No.: US 2007/0037316 A1
(43) Pub. Date: Feb. 15, 2007

(54) Memory cell contact using spacers

(75) Inventors: H. M. Manning, Eagle, ID (US); Kunal R. Parekh, Boise, ID (US)

Correspondence Address: DICKSTEIN SHAPIRO LLP, 1825 EYE STREET NW, Washington, DC, 20006-5403, US

(73) Assignee: Micron Technology, Inc.

(21) Appl. No.: 11/199,252

(22) Filed: Aug. 9, 2005

(51) Int. Cl. H01L 21/06

(52) U.S. Cl. 438/102

(57) ABSTRACT

A method of forming contacts used in a memory device. The method involves forming a via in an insulating layer, forming spacers on sidewalls of the via, and filling the via with a conductive material. The resulting contact has rounded upper corners to improve the reliability of the memory device. Also disclosed is a subsequent recessing and refilling method to mitigate keyholes in the memory device contacts.

### FIELD OF THE INVENTION

The present invention relates to the field of semiconductor devices and, in particular, to the formation of contacts for memory and other integrated circuit devices.

### BACKGROUND OF THE INVENTION

A well known semiconductor memory component is random access memory (RAM). RAM permits repeated read and write operations on memory elements. Typically, RAM devices are volatile, in that stored data is lost once the power source is disconnected or removed. Examples of RAM devices include dynamic random access memory (DRAM), synchronized dynamic random access memory (SDRAM) and static random access memory (SRAM). In addition, DRAMS and SDRAMS also typically store data in capacitors, which require periodic refreshing to maintain the stored data.

Recently, resistance variable memory elements, which include Programmable Conductive Random Access Memory (PCRAM) elements employing a chalcogenide material, have been investigated for suitability as semi-volatile and non-volatile random access memory devices. One such PCRAM device is disclosed in U.S. Pat. No. 6,348,365, assigned to Micron Technology Inc. and incorporated herein by reference. In typical PCRAM devices, conductive material, such as silver, is moved into and out of the chalcogenide material to alter the cell resistance. Thus, the resistance of the chalcogenide material can be programmed to stable higher resistance and lower resistance states. The programmed lower resistance state can remain intact for a long period, typically ranging from hours to weeks, after the voltage potentials are removed.

One aspect of fabricating PCRAM cells, which also occurs in fabrication of other integrated circuit devices, involves contacts used for connecting PCRAM memory cells to integrated circuitry formed several layers beneath the cells. Often, because of the high aspect ratio of long vias, contacts provided therein have either sharp corners or keyholes (or both) created during the contact formation. The sharp corners are created by the long, vertical sidewalls of vias. Keyholes are the result of the chemical mechanical polishing and etch-back steps being unable to create a completely smooth topography as well as contact etch profiles that have varying dimensions than the depth of the contact.

The sharp corners and/or keyholes result in inconsistent and unreliable switching of the memory device. Put another way, these problems make the cell unable to reliably switch between high and low resistance states. Such problems also reduce memory device yield and the lifetime of a memory cell is potentially cut short. Therefore, it is important in the fabrication of integrated circuit contacts, including those employing PCRAM memory cells, to create a smooth-surfaced planar, or slightly recessed, conductive plug to which the memory cell material may be deposited.

Accordingly, there is a need for conductive contacts having a smooth surface with a lack of keyhole defects. These contacts are, for example, desired for use in a resistance variable memory device. A simple method of forming the advantageous memory cells is also desired.

### BRIEF SUMMARY OF THE INVENTION

Exemplary embodiments of the invention provide contacts having smooth edges for use in an integrated circuit. Exemplary methods of forming the contacts are also disclosed. The methods involve forming a via in an insulating layer, forming spacers on sidewalls of the via, and filling the via with a conductive material. The exemplary contacts have rounded upper corners for the contact that may improve reliability. The spacers may be made of a nitride material.

In accordance with one exemplary embodiment, the integrated circuit is a PCRAM memory device.

In accordance with another exemplary embodiment, the invention can mitigate keyholes in the contacts by recessing and refilling the conductive material used to form the contact.

### BRIEF DESCRIPTION OF THE DRAWINGS

The above-discussed and other features and advantages of the invention will be better understood from the following detailed description, which is provided in connection with the accompanying drawings, in which:

FIG. 1 is a cross-sectional view of a portion of an exemplary memory device constructed in accordance with the invention;

FIG. 2 is a cross-sectional view of a portion of the exemplary memory device of FIG. 1 during a stage of fabrication;

FIG. 3 is a cross-sectional view of a portion of the exemplary memory device of FIG. 1 during a stage of fabrication subsequent to that shown in FIG. 2;

FIG. 4 is a cross-sectional view of a portion of the exemplary memory device of FIG. 1 during a stage of fabrication subsequent to that shown in FIG. 3;

FIG. 5 is a cross-sectional view of a portion of the exemplary memory device of FIG. 1 during a stage of fabrication subsequent to that shown in FIG. 4;

FIG. 5a is a cross-sectional view of a portion of an alternative, exemplary memory device during a stage of fabrication subsequent to that shown in FIG. 4;

FIG. 6 is a cross-sectional view of a portion of the exemplary memory device during a stage of fabrication subsequent to that shown in either FIG. 5 or FIG. 5a;

FIG. 7 is a cross-sectional view of a portion of the exemplary memory device during a stage of fabrication subsequent to that shown in FIG. 6;

FIG. 8 is a cross-sectional view of a portion of the exemplary memory device during a stage of fabrication subsequent to that shown in FIG. 7; and

FIG. 9 illustrates a computer system having a memory element in accordance with the invention.

### DETAILED DESCRIPTION OF THE INVENTION

In the following detailed description, reference is made to various specific embodiments of the invention. These embodiments are described with sufficient detail to enable those skilled in the art to practice the invention. It is to be understood that other embodiments may be employed, and that various structural, logical and electrical changes may be made without departing from the spirit or scope of the invention.

The term “substrate” used in the following description may include any supporting structure including, but not limited to, a semiconductor substrate that has an exposed substrate surface. A semiconductor substrate should be understood to include silicon, silicon-on-insulator (SOI), silicon-on-sapphire (SOS), doped and undoped semiconductors, epitaxial layers of silicon supported by a base semiconductor foundation, and other semiconductor structures. When reference is made to a semiconductor substrate or wafer in the following description, previous process steps may have been utilized to form regions or junctions in or over the base semiconductor or foundation. The substrate need not be semiconductor-based, but may be any support structure suitable for supporting an integrated circuit.

The term “resistance variable memory element” is intended to include any memory element, including programmable conductor memory elements, semi-volatile memory elements, non-volatile memory elements, and other memory elements that exhibit a resistance change in response to an applied voltage.

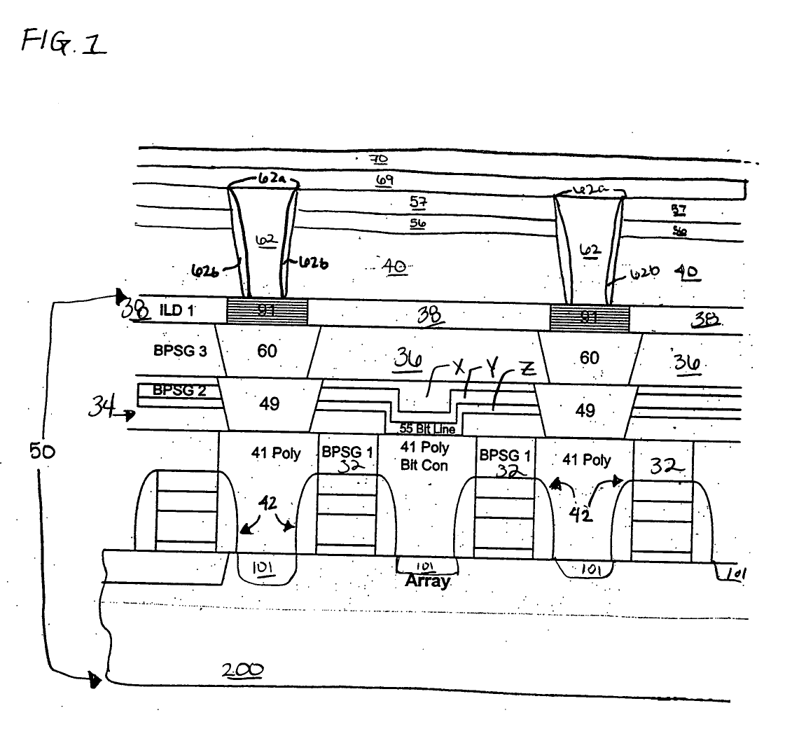

The invention is now explained with reference to the figures, which illustrate exemplary embodiments and where like reference numbers indicate like features. FIG. 1 shows array circuitry portions of an exemplary resistance variable memory device 100 constructed in accordance with the invention. It should be understood that the portions shown are illustrative of one embodiment of the invention, and that the invention encompasses other memory and non-memory integrated circuit devices that can be formed using different materials and processes than those described herein. The memory device 100 has contacts 62 as formed in connection with exemplary embodiments discussed below. As shown in FIG. 1, the contacts 62 have rounded corners 62a created by spacers 62b formed on the sidewalls of a via in the contact 62. Further, it should be noted that the exemplary contacts 62 do not have keyhole defects.

For exemplary purposes only, memory device 100 is shown with an example of circuitry 50 which can consist of the elements now described. In the array portions of a substrate 200, transistors 42 are formed having source/drain active regions 101 in the substrate 200. A first insulating layer 32, e.g., a boro-phospho-silicate glass (BPSG) layer, is formed over gatestacks of the transistors 42. Conductive plugs 41, which may be formed of polysilicon, are formed in the first insulating layer 32 connecting to the source drain regions 101 in the substrate 200. A second insulating layer 34 is formed over the first insulating layer 32, and may again comprise a BPSG layer. Conductive plugs 49 are formed in the second insulating layer 34 and are electrically connected to the conductive plugs 41 in the first insulating layer 32, which connect through some of plugs 41 to selected transistors 42. A conductive bit line 55 is formed between the conductive plugs 49 over the second insulating layer 34. The illustrated bit line 55 has layers X, Y, Z that may be formed of silicon nitride, tungsten, tungsten and tungsten nitrdie, respectively. A third insulating layer 36, which may also be a BPSG layer, is formed over the second insulating layer 34; openings in the insulating layer 36 are formed and filled with a conductive material to form conductive plugs 60. Next, metallization layers having conductive traces and/or contacts 91 are formed over the third insulating layer 36 and are insulated with an interlevel dielectric (ILD) layer 38.

Referring now to FIGS. 2-8, exemplary steps in a method of forming the exemplary contacts 62 for memory device 100 in accordance with the invention are now described. It should be understood that the description of materials and fabrication steps just described for circuitry 50 were illustrative only, and that other types of integrated circuitry are within the scope of the invention. Thus, for purposes of the remaining fabrication steps, the layers of the circuitry 50 are depicted in block form only in the fabrication steps described with reference to FIGS. 2-8.

Turning to FIG. 2, an insulating layer 40 is formed over the circuitry 50. In accordance with a preferred embodiment, the insulating layer 40 can be made of either boro-phospho-silicate glass (BPSG) or phospho-silicate glass (PSG). Other types of insulting material could also be used to form the insulating layer 40. As shown in FIG. 2, additional insulating layers 56, 57 can also be formed over the insulating layer 40. In accordance with a preferred embodiment, these additional insulating layers are a nitride layer 57 and an oxide layer 56.

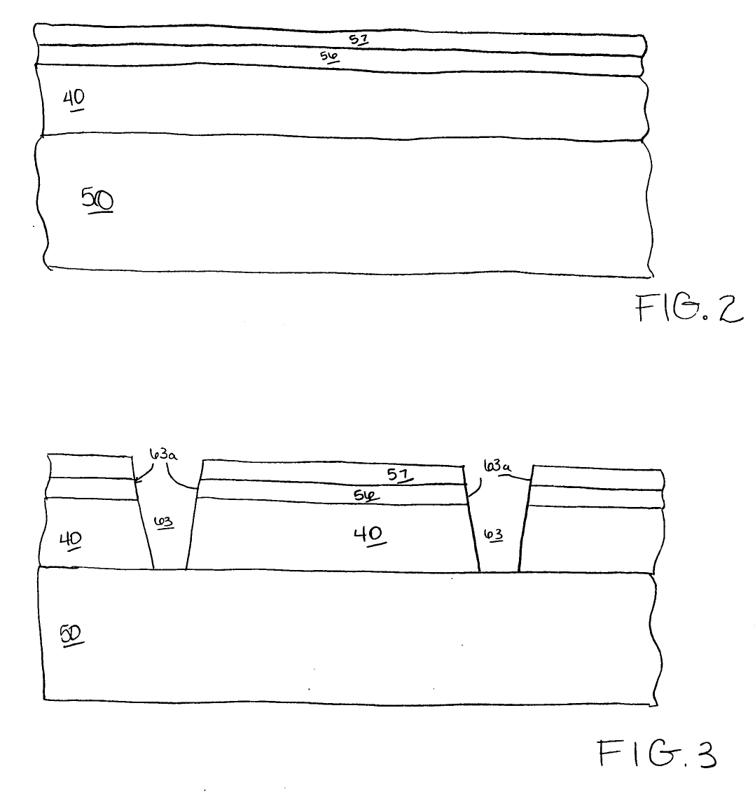

Next, referring to FIG. 3, a via 63 is etched in the insulating layers 40, 56, 57. The via 63 can have a high aspect ratio. The via 63 can be formed using known trench-forming techniques, and may be formed having slanted sidewalls 63a. Next, as shown in FIG. 4, sidewall spacers 62b are formed on the via sidewalls 63a. The spacers 62a can be formed using known techniques such as blanket depositing an insulating material, followed by an anisotropic dry etch step. This results in a spacer 62a formed along the entire, vertical length of the sidewalls 63a. The spacers 62b can be formed of any insulating material, including oxides. In accordance with a preferred embodiment, the spacers 62b are made of a nitride material, including but not limited to, silicon nitride and oxynitride. Other materials that can be used for the spacers include silicon oxide, and other metal oxides, including but not limited to, aluminum oxide and hafnium oxide.

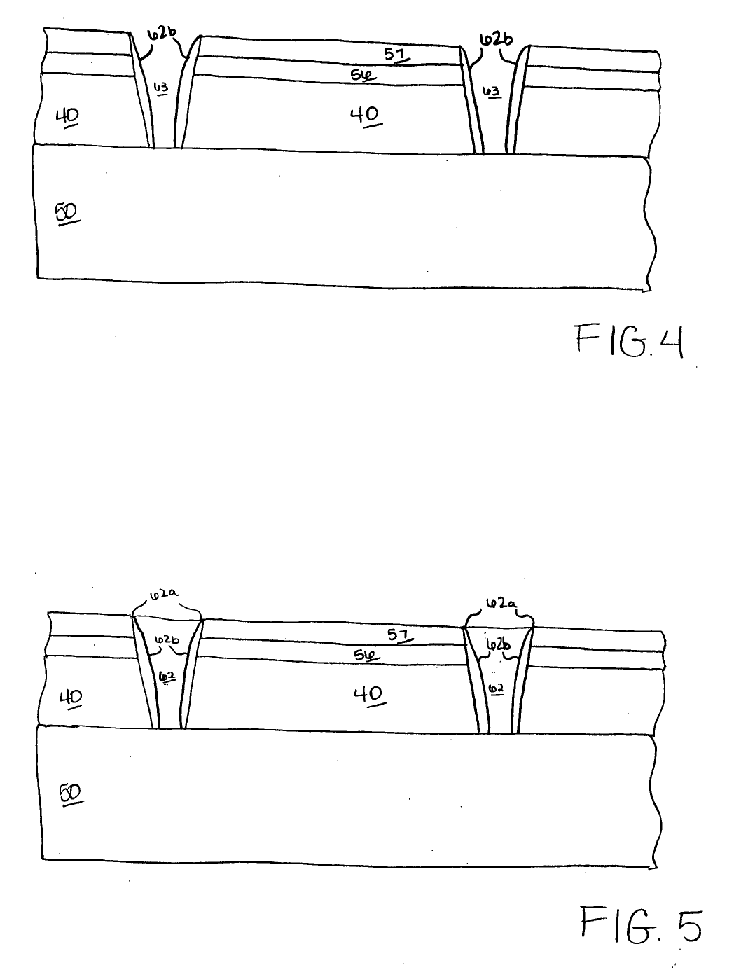

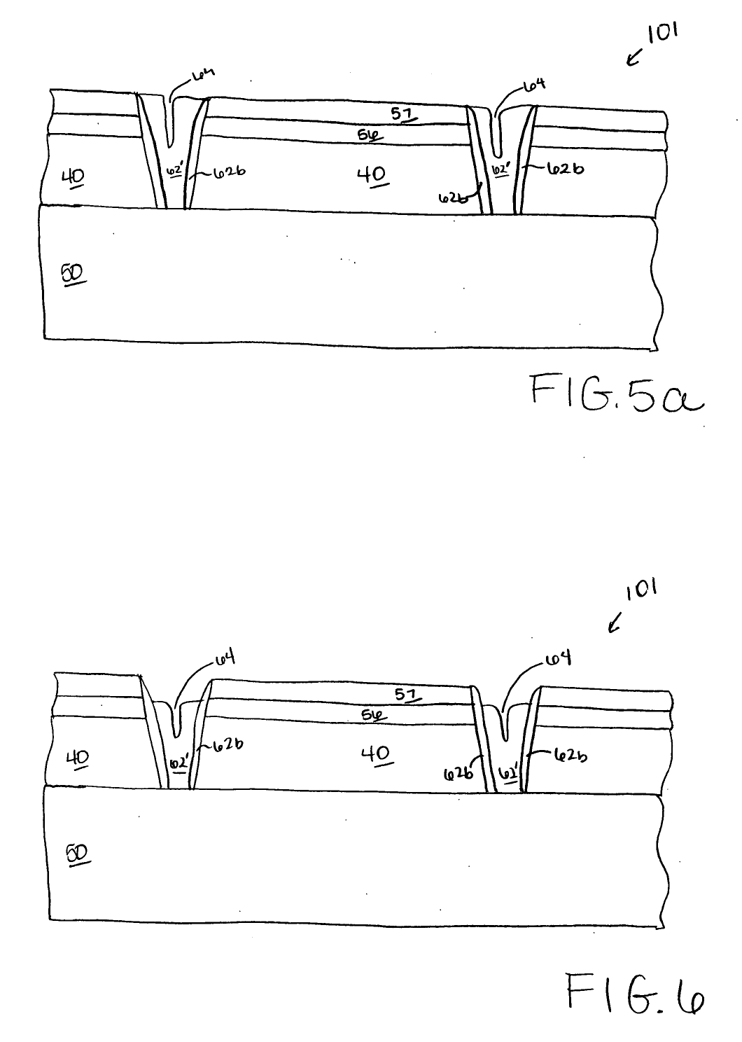

It should be noted that due to the nature of spacer formation, the spacers 62b have rounded corners 62a (FIG. 5) at the top of the via 63. The rounded corners prevent the reliability problems that are seen in traditional contacts. In addition, the spacers 62b also decrease the amount of area in the contact that has to be filled with conductive material. As such, the electrical characteristics of the contact 62 may be improved by reducing the pore size for conductive material, as generally, electrical characteristics are improved with a reduction in element size.

Next, a conductive material for contact 62 is deposited in the via 63. This step may be performed by blanket depositing a conductive material layer over the entire surface of the device or by selectively depositing the material in the via 63. In accordance with a preferred embodiment of the invention, the conductive material is a tungsten alloy, such as Ti/TiN/W or TiN/W. The material selected for this bulk fill needs to be conductive, and is preferably able to fill high aspect ration openings.

Next, as shown in FIG. 5, the conductive material for contact 62 is planarized with the top surface of the insulating layer 57. Preferably, the planarization is performed such that the surface of the conductive material of contact 62 is planar with, or just slightly recessed below, the top surface of the conductive layer 57 such that it is substantially planar with the top surface.

At this stage in fabrication, memory cell formation and patterning can now occur, using the conductive material of contact 62 as a base electrode of the memory cell, as described in more detail below. Alternatively, further processing can be performed to further mitigate the potential that the contact 62 suffer from keyholes. FIG. 5a shows an exemplary memory device 101 during a stage of fabrication subsequent to that shown in FIG. 4. The only difference between the memory device 100 (FIG. 5) and the memory device 101 (FIG. 5a) is the presence of a keyhole 64 in the contact 62′ of memory device 101.

In order to enhance the reliability of memory device 101 by mitigating the keyhole 64 in the contact 62′, the following fabrication steps can be performed in accordance with an exemplary method. It should be understood, however, that these steps can be performed during the fabrication of all memory cells, including memory cell 100, after the steps depicted in FIG. 5, without determining whether keyholes are actually present during fabrication.

As shown in FIG. 6, the conductive material in the contact 62′ is recessed even further below the surface of the insulating layer 57. This step can be performed after the processing to produce the FIG. 5 substrate, using known dry or wet etch methods compatible with the conductive material of the contact 62′. A conductive material is then deposited to cover the keyhole 64.

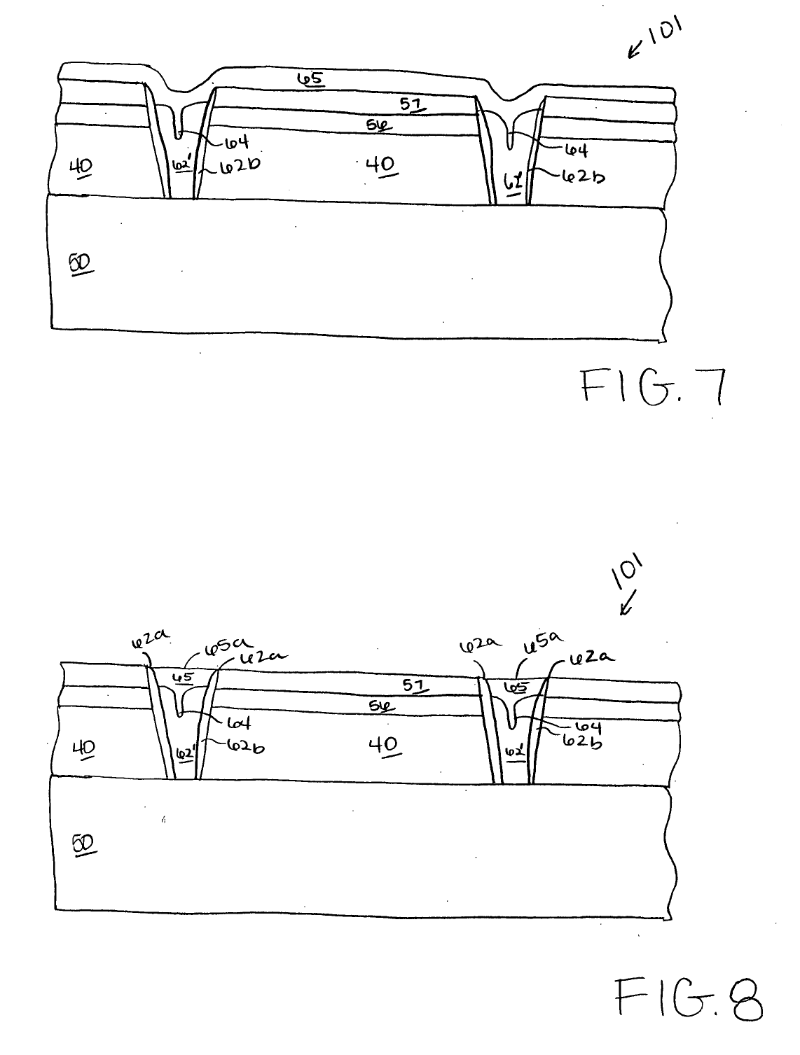

As shown in FIG. 7, a conductive material 65 may be blanket deposited over the surface of the structure, including over the keyhole 64 and the conductive contact 62′. In a preferred embodiment, the conductive material 65 is a tungsten-containing material (such as alloys Ti/TiN/W or TiN/W) that is deposited using physical vapor deposition. The conductive, backfill material 65 may be either the same or different than the original conductive material 62′. The backfill material needs to be compatible with the bulk fill material (conductive contact 62′) to insure good electrical connection. Particular deposition methods, such as chemical vapor deposition (CVD) and physical vapor deposition (PVD) may be more suitable to producing the desired bulkfill/backfill conductor characteristics. Examples of possible bulkfill/backfill material combinations include (CVD) W/(PVD) W, (CVD) W/Al, (CVD) W/TiN, (CVD) W/TaN.

As shown in FIG. 8, planarization is then performed such that the top surface of the conductive material 65 is either even with, or just below, the top surface of the insulating layer 57. Accordingly, the final contact structure beneficially has rounded corners 62a as well as a top surface 65a that is keyhole free. It should be noted, however, that it may be important that the conductive material 62′ top surface is not recessed too deep, or else the physical vapor deposition of conductive material 65 will not be effective in backfilling the contact 62 without leaving seams.

At this stage in fabrication, memory cell formation and patterning can now occur. With reference to FIG. 1, exemplary methods of completing the memory device 100 will now be described. Cell material 69 is deposited on the array. The cell material 69 may include resistance variable cell material, like the materials necessary for construction of PCRAM memory cells constructed according to the teachings of U.S. Pub. Appl. Nos. 2003/0155589 and 2003/0045054, each assigned to Micron Technology Inc., and incorporated herein by reference. Appropriate PCRAM cell materials include layers of germanium selenide or germanium antimony telluride, and silver-containing layers creating a resistance variable memory device 100. Finally, a top electrode 70 is deposited over the cell material 69 as shown in FIG. 1. The top electrode 70 contacts the cell 69. The electrode 70 can be patterned as desired. For example, the electrode 70 layer may be blanket deposited over the array; or alternatively, an electrode 70 may be deposited in a pre-determined pattern, such as in stripes over the array. In the case of PCRAM cells, the top electrode 70 should be a conductive material, such as tungsten or tantalum, but preferably not containing silver. Also, the top electrode 70 may comprise more than one layer of conductive material if desired.

At this stage, the memory device 100 is essentially complete. The memory cells are defined by the areas of layer 69 located between the conductive contacts 62 and the electrode 70. Other fabrication steps to insulate the electrode 70 and connect it with peripheral circuits, using techniques known in the art, are now performed to complete fabrication. Other steps will also be necessary to passivate and package the memory device.

The embodiments described above refer to the formation of a memory device 100, 101 structure in accordance with the invention. It must be understood, however, that the invention contemplates the formation of other integrated circuit elements, and the invention is not limited to the embodiments described above. Moreover, although described as a single memory device 100, 101, the device 100, 101 can be fabricated as a part of a memory array and operated with memory element access circuits.

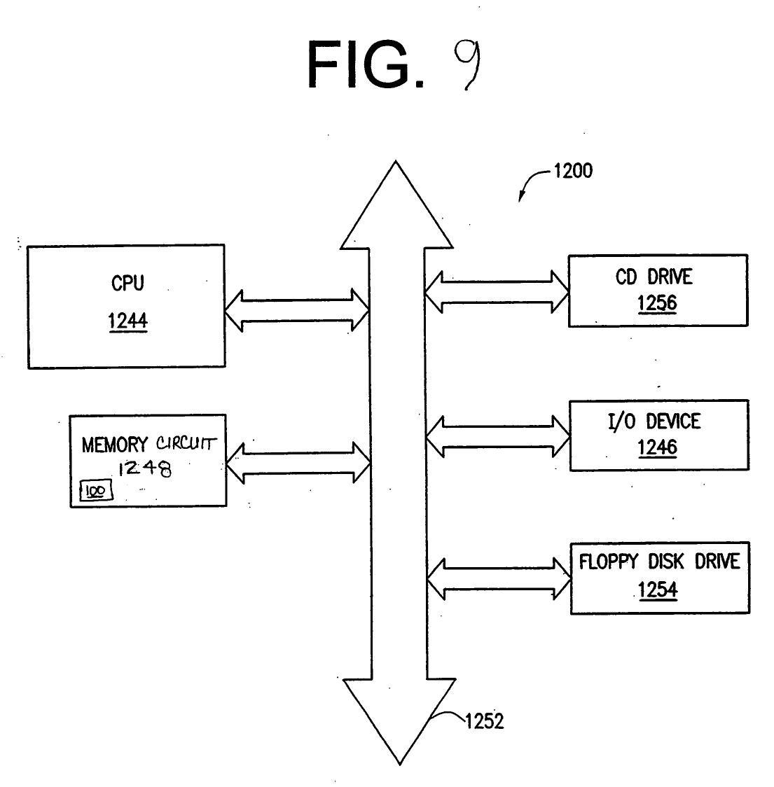

FIG. 9 is a block diagram of a processor-based system 1200, which includes a memory circuit 1248, for example a PCRAM circuit employing non-volatile memory devices 100 fabricated in accordance with the invention. The processor system 1200, such as a computer system, generally comprises a central processing unit (CPU) 1244, such as a microprocessor, a digital signal processor, or other programmable digital logic devices, which communicates with an input/output (I/O) device 1246 over a bus 1252. The memory 1248 communicates with the system over bus 1252 typically through a memory controller.

In the case of a computer system, the processor system may include peripheral devices such as a floppy disk drive 1254 and a compact disc (CD) ROM drive 1256, which also communicate with CPU 1244 over the bus 1252. Memory 1248 is preferably constructed as an integrated circuit, which includes one or more resistance variable memory elements 100. If desired, the memory 1248 may be combined with the processor, for example CPU 1244, in a single integrated circuit.

The above description and drawings are only to be considered illustrative of exemplary embodiments which achieve the features and advantages of the invention. Modification and substitutions to specific process conditions and structures can be made without departing from the spirit and scope of the invention. Accordingly, the invention is not to be considered as being limited by the foregoing description and drawings, but is only limited by the scope of the appended claims.

What is claimed as new and desired to be protected by Letters Patent of the United States is:

1. A method of forming a memory device, the method comprising:
forming a circuit over a semiconductor substrate;
forming at least one first insulating layer having a top surface over said circuit;
forming a via in said at least one first insulating layer, said via having sidewalls;
forming a spacer along said via sidewalls from a top to a bottom of said via;
filling said via with a first conductive material;
planarizing said first conductive material; and
forming at least one memory cell over said via and said insulating layer.

2. The method of claim 1, wherein the at least one insulating layer is one of a PSG or a BPSG layer.

3. The method of claim 2, wherein said conductive material comprises tungsten.

4. The method of claim 1, wherein the act of planarizing said first conductive material comprises making a top surface of the conductive material substantially even with the top surface of said insulating layer.

5. The method of claim 1, further comprising the act of recessing the conductive material to a level below said top surface of said insulating layer.

6. The method of claim 5, wherein recessing comprises etching the first conductive material.

7. The method of claim 5, further comprising the act of forming a second conductive material over the first, recessed conductive material.

8. The method of claim 7, wherein said first conductive material is the same as the second conductive material.

9. The method of claim 7, wherein each of said first and said second conductive materials comprise tungsten alloys.

10. The method of claim 7, wherein the act of forming a spacer comprises forming a nitride material along said sidewalls.

11. The method of claim 10, wherein said spacer has a rounded edge where said nitride material contacts said insulating layer.

12. The method of claim 1, wherein the at least one memory cell is a resistance variable memory cell.

13. The method of claim 1, wherein the at least one memory cell is a PCRAM memory cell.

14. The method of claim 13, wherein the act of forming said at least one memory cell comprises forming at least one layer of germanium selenide glass.

15. The method of claim 14, wherein the act of forming said at least one memory cell further comprises forming at least one layer comprising silver in communication with said at least one layer of germanium selenide glass.

16. The method of claim 13, wherein the act of forming said at least one memory cell comprising forming at least one layer of germanium antimony telluride.

17. The method of claim 1, further comprising the step of forming an electrode layer over the at least one memory cell.

18. A method of forming an integrated circuit device, comprising the acts of:
forming a circuit;
forming at least one insulating layer having a top surface over said circuit;
forming at least one opening in said insulating layer, the opening having sidewalls extending from a top surface to an underlying layer;
forming an insulating spacer along a length of said sidewalls;
forming a first conductive material within said opening;
recessing at least a portion of said first conductive material to form a partial opening; and
refilling said partial opening with a second conductive layer.

19. The method of claim 18, wherein the act of recessing comprises etching a portion of said first conductive layer, using one of a wet etch or a dry etch.

20. An electrical device, comprising:
integrated circuitry formed over a substrate;
at least one insulating layer formed over said integrated circuitry, said insulating layer having a top surface and a plurality of openings through said insulating layer to an underlying layer, said openings having sidewalls vertically through said insulating layer; and
a first conductive layer formed in said openings and in contact with a spacer, the spacer being formed on each of said sidewalls, said conductive layer being substantially planar with said top surface of said insulating layer.

21. The device of claim 20, wherein said conductive material comprises tungsten.

22. The device of claim 21, wherein said spacers comprise nitride.

23. The device of claim 22, further comprising a second conductive layer being formed in said openings and beneath said first conductive layer.

24. The device of claim 20, further comprising resistance variable memory cell material deposited over the first conductive layer and the insulating layer.

25. The device of claim 24, wherein the device is a PCRAM memory device.

26. The device of claim 24, wherein the memory cell material comprises layers of germanium selenide, chalcogenide glass and silver.

27. The device of claim 20, wherein said spacer has rounded edges where it contacts with said insulating layer.

28. A memory system comprising:
a resistance variable memory device, said device comprising:
an array of resistance variable memory cells formed on a substrate, each cell comprising:
integrated circuitry formed over a substrate; and
at least one contact having round corners, the contact comprising a conductive plug filling a via formed in an insulating layer and having insulating spacers.

29. The system of claim 28, wherein said conductive plug comprises a first and second conductive layer formed one over the other.

30. The system of claim 29, wherein said first and second conductive layers comprise tungsten.

31. The system of claim 30, wherein said insulating spacers comprise nitride.
